(19) United States
(12) Patent Application Publication
(10) Pub. No.: US 2015/0249449 A1
(43) Pub. Date: Sep. 3, 2015

(54) POWER SWITCH CELL WITH ADAPTIVE BODY BIAS

(71) Applicant: QUALCOMM INCORPORATED 5775 Morehouse DriveSan Diego92121-1714, San Diego, CA (US)

(72) Inventors: Yanfei Cai, Shanghai (CN); Xiaoguang Chen, Shanghai (CN); Zewen Shi, Shanghai (CN)

(21) Appl. No.: 14/430,387

(22) PCT Filed: Sep. 27, 2012
(86) PCT No.: PCT/CN2012/082122

§ 371 Date: Mar. 23, 2015

(51) Int. Cl. H03K 17/687

(52) U.S. Cl. CPC H03K 17/687

(57) ABSTRACT

A circuit and a method are disclosed for adjusting a body bias voltage applied to a power gating switch. The circuit comprises: a first supply voltage (916), a body bias generator (918) formed from a plurality of series connected MOSFETs coupled to a second supply voltage (928) and an adaptive switch (910) providing an output coupled to either the first supply voltage or the body bias generator output (926), wherein the output of the adaptive switch is a first body bias voltage when coupled to the first supply voltage and is a second body bias voltage when coupled to the body bias generator output such that the first body bias voltage is greater than the second body bias voltage when configured as a gating header switch and the first body bias voltage is less than the second body bias voltage when configured as a gating footer switch.

### FIELD OF THE PRESENT INVENTION

This disclosure generally relates to power switch cells and more specifically to header or footer switches having reduced area requirements.

### BACKGROUND OF THE INVENTION

To increase efficiency, power gating techniques have been developed to selectively supply power to one or more subsets of circuitry, allowing them to be depowered at times their function is not required. As such, areas of a circuit, known as cells, may be controlled by a power switch. Thus, the use of power switch cells may reduce the current consumed by the circuit when in an OFF condition, which is a desirable attribute for modern integrated circuits. The switches are typically operated by signals generated by a control logic block that determines when the cells may be disabled to reduce power use.

Generally, a metal oxide semiconductor field effect transistor (MOSFET) may be a P-type (PMOS) or an N-type (NMOS.) A PMOS may be used as the switch for the cell as a header switch to selectively couple the circuit to a power rail. Similarly, an NMOS may be used as a footer switch to selectively couple the circuit to ground. As will be appreciated, a suitable switch exhibits low current leakage when OFF and low resistance when ON. Since ON resistance is proportional to the physical dimensions of the CMOS, long channel and large width devices are currently used to reduce leakage and provide low ON resistance.

However, such strategies are at odds with attempts to reduce the overall size of integrated circuits, such as through reductions in semiconductor process size. These aspects may be viewed in terms of the area penalty of a power switch cell, defined as the ratio of the area of the switch to the area of the circuit controlled by the switch. The area penalty increases by the reciprocal ratio of the square of scaling factor representing the reduction in process size, making these impacts particularly significant in current sub-45 nm processes. As a result, it would be desirable to provide a power switch cell with suitably low ON resistance while also allowing a reduction in the area penalty of the switch.

Accordingly, what have been needed are systems and methods for implementing header or footer switches having reduced area requirements. There is also a need for power gating techniques providing reduced on resistance and low leakage current. This specification discloses systems and methods for satisfying these and other needs.

### SUMMARY OF THE INVENTION

In accordance with the above needs and those that will be mentioned and will become apparent below, this specification discloses a circuit for adjusting a body bias voltage applied to a power gating switch, including a first supply voltage, a body bias generator formed from a plurality of series connected MOSFETs coupled to a second supply voltage, wherein a body bias generator output is taken from a node between a source of a first MOSFET of the plurality of series connected MOSFETs and a drain of a second MOSFET of the plurality of series connected MOSFETs, and an adaptive switch providing an output coupled to either the first supply voltage or the node of the body bias generator, wherein the output of the adaptive switch is a first body bias voltage when coupled to the first supply voltage and is a second body bias voltage when coupled to the node of the body bias generator such that the first body bias voltage is greater than the second body bias voltage for gating header switch and the first body bias voltage is less than the second body bias voltage for gating footer switch.

In one aspect, the circuit may include a power gating switch having a body node operatively coupled to the output of the adaptive switch, wherein the power gating switch may be a PMOS gating header switch or an NMOS gating footer switch.

One embodiment includes control logic configured to generate control signals to operate the power gating switch and the adaptive switch. Notably, the power gating switch may be a PMOS gating header switch and the control logic may be configured to generate a first control signal and a second control signal that is the inverse of the first control signal such that the first control signal is applied to a gate of the gating header switch to activate the gating header switch when the first control signal is set to a logical ‘0’ and the second control signal causes the adaptive switch to output the second body bias voltage and such that the first control signal is applied to the gate of the gating header switch to deactivate the gating header switch when the first control signal is set to a logical ‘1’ and the second control signal causes the adaptive switch to output the first body bias voltage. Further, the adaptive switch may be a PMOS having a source connected to the first supply voltage, a drain connected to the output of the adaptive switch and a gate receiving the second control signal and an NMOS having a drain connected to the node of the body bias generator, a source connected to the output of the adaptive switch and a gate receiving the second control signal.

In another aspect, the circuit may also include a body bias switch configured to selectively couple the second supply voltage to the plurality of series connected MOSFETs when the output of the adaptive switch is coupled to the node of the body bias generator.

In yet another aspect, the plurality of series connected MOSFETs may operate in a moderate inversion mode when the output of the adaptive switch is coupled to the node of the body bias generator.

In some embodiments, the first supply voltage may be the same as the second supply voltage.

Other aspects of this disclosure are directed to a method for adjusting a body bias voltage applied to a power gating switch, including the steps of providing an adaptive body bias module having a first supply voltage, a body bias generator formed from a plurality of series connected MOSFETs coupled to a second supply voltage, wherein a body bias generator output is taken from a node between a source of a first MOSFET of the plurality of series connected MOSFETs and a drain of a second MOSFET of the plurality of series connected MOSFETs, and an adaptive switch having an output, generating a first body bias voltage by coupling the output of the adaptive switch to the first supply voltage, and generating a second body bias voltage by coupling the output of the adaptive switch to the node of the body bias generator, wherein the first body bias voltage is greater than the second body bias voltage.

In some embodiments, a power gating switch having a body node operatively may be coupled to the output of the adaptive switch. For example, the power gating switch may be a PMOS gating header switch such that the method includes operating the gating header switch in an OFF mode when generating the first body bias voltage and operating the gating header switch in an ON mode when generating the second body bias voltage. Alternatively, the power gating switch may be an NMOS gating footer switch such that the method includes operating the gating footer switch in an OFF mode when generating the first body bias voltage and operating the gating footer switch in an ON mode when generating the second body bias voltage.

In other aspects, the method may also include generating control signals configured to operate the power gating switch and the adaptive switch. For example, the power gating switch may be a PMOS gating header switch such that the method also includes the steps of applying a first control signal set to logical ‘0’ to a gate of the gating header switch to activate the gating header switch and a second control signal set to logical ‘1’ to the adaptive switch to cause the adaptive switch to output the second body bias voltage and applying the first control signal set to logical ‘1’ to the gate of the gating header switch to deactivate the gating header switch and the second control signal set to logical ‘0’ to the adaptive switch to cause the adaptive switch to output the first body bias voltage. Further, the adaptive switch may be a PMOS having a source connected to the first supply voltage, a drain connected to the output of the adaptive switch and a gate receiving the second control signal and an NMOS having a drain connected to the node of the body bias generator, a source connected to the output of the adaptive switch and a gate receiving the second control signal.

Further aspects of the disclosure may include selectively coupling the second supply voltage to the plurality of series connected MOSFETs when the output of the adaptive switch is coupled to the node of the body bias generator. In another embodiment, the method may include operating the plurality of series connected MOSFETs in a moderate inversion mode when the output of the adaptive switch is coupled to the node of the body bias generator. In such embodiments, the plurality of series connected MOSFETs comprises three NMOS.

Yet another aspect of the disclosure includes using the same supply voltage for the first supply voltage and the second supply voltage.

### BRIEF DESCRIPTION OF THE DRAWINGS

Further features and advantages will become apparent from the following and more particular description of the preferred embodiments of the invention, as illustrated in the accompanying drawings, and in which like referenced characters generally refer to the same parts or elements throughout the views, and in which:

FIG. 1 depicts a gating header switch, suitable for use with embodiments of the invention;

FIG. 2 depicts a gating footer switch, suitable for use with embodiments of the invention;

FIG. 3 depicts a grid-type power gating architecture representing a 45 nm process, suitable for use with embodiments of the invention;

FIG. 4 depicts a grid-type power gating architecture representing a 28 nm process, suitable for use with embodiments of the invention;

FIG. 5 depicts the relationship between area penalty and process size for a gating header switch and a gating footer switch;

FIG. 6 depicts the relationship between body bias voltage and on resistance for a PMOS gating header switch;

FIG. 7 depicts the relationship between body bias voltage and width ratio for a PMOS gating header switch;

FIG. 8 depicts a power switch cell having an adaptive body bias module operatively coupled to a gating header switch, according to one embodiment of the invention;

FIG. 9 is circuit schematic for an adaptive body bias module operatively coupled to a gating header switch, according to one embodiment of the invention;

FIG. 10 is a graph depicting the voltage of control signals and the body bias voltage produced by an adaptive body bias module, according to one embodiment of the invention;

FIG. 11 depicts the result of a Monte-Carlo simulation for an adaptive body bias module, according to one embodiment of the invention;

FIG. 12 depicts the active current consumption of an adaptive body bias module at signoff process corners, according to one embodiment of the invention;

FIG. 13 depicts the standby current consumption of an adaptive body bias module at signoff process corners, according to one embodiment of the invention.

### DETAILED DESCRIPTION OF THE INVENTION

At the outset, it is to be understood that this disclosure is not limited to particularly exemplified materials, architectures, routines, methods or structures as such may, of course, vary. Thus, although a number of such options, similar or equivalent to those described herein, can be used in the practice or embodiments of this disclosure, the preferred materials and methods are described herein.

It is also to be understood that the terminology used herein is for the purpose of describing particular embodiments of this disclosure only and is not intended to be limiting.

The detailed description set forth below in connection with the appended drawings is intended as a description of exemplary embodiments of the present invention and is not intended to represent the only exemplary embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the specification. It will be apparent to those skilled in the art that the exemplary embodiments of the specification may be practiced without these specific details. In some instances, well known structures and devices are shown in block diagram form in order to avoid obscuring the novelty of the exemplary embodiments presented herein.

For purposes of convenience and clarity only, directional terms, such as top, bottom, left, right, up, down, over, above, below, beneath, rear, back, and front, may be used with respect to the accompanying drawings or chip embodiments. These and similar directional terms should not be construed to limit the scope of the invention in any manner.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

“Complementary logic,” which refers to logic circuitry involving both P-channel and N-channel transistors, is often more commonly referred to as CMOS (Complementary Metal Oxide Semiconductor) logic even though the transistors making up the logic circuitry may not have metal gates and may not have oxide gate dielectrics.

The terms second level and first level, high and low and 1 and 0, as used in the following description may be used to describe various logic states as known in the art. Particular voltage values of the second and first levels are defined arbitrarily with regard to individual circuits. Furthermore, the voltage values of the second and first levels may be defined differently for individual signals such as a clock and a digital data signal. Although specific circuitry has been set forth, it will be appreciated by those skilled in the art that not all of the disclosed circuitry is required to practice the invention. Moreover, certain well known circuits have not been described, to maintain focus on the invention. Similarly, although the description refers to logical “0” and logical “1” or low and high in certain locations, one skilled in the art appreciates that the logical values can be switched, with the remainder of the circuit adjusted accordingly, without affecting operation of the present invention.

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

Unless defined otherwise, all technical and scientific terms used herein have the same meaning as commonly understood by one having ordinary skill in the art to which the disclosure pertains.

Further, all publications, patents and patent applications cited herein, whether supra or infra, are hereby incorporated by reference in their entirety.

Finally, as used in this specification and the appended claims, the singular forms “a, “an” and “the” include plural referents unless the content clearly dictates otherwise.

As will be described in detail below, the techniques of this disclosure involve the use of an adaptive body bias (ABB) module to control the body bias applied to the switching transistor of power switch cell. In the context of a header switch, the circuit may be configured to reduce the body bias voltage applied to the switch when ON to provide a forward body bias and to increase the body bias voltage applied to the switch when OFF. The decreased body bias voltage reduces the threshold voltage of the transistor to provide decreased ON resistance. Conversely, the increased body bias voltage increases the threshold voltage of the transistor to provide high impedance and low current leakage. Preferably, the ABB circuit may be responsive to the control signals used to switch the power switch cell between ON and OFF.

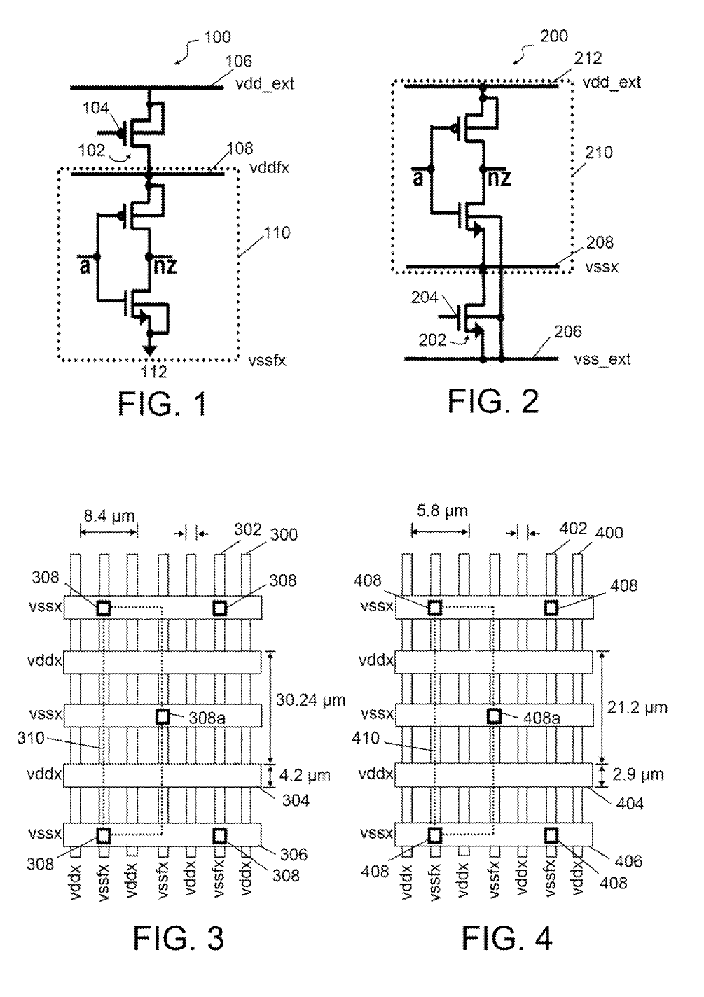

A primary function of a power switch cell is to reduce current flowing through a circuit when in an OFF, or sleep, mode while allowing normal operation in an ON, or active, mode. Power management is an important criterion for modern integrated circuits and the use of power switch cells is a widely used method for implementing corresponding power management techniques. As will be appreciated, an NMOS or PMOS typically may be used as a switching transistor for a header switch or a footer switch to control power delivery to designated blocs of an integrated circuit. Desirable attributes for power cell switches are low current leakage in OFF mode, so that minimal current flows when the circuit block is inactive and correspondingly little power is consumed, and a low ON resistance, so that minimal energy is wasted when the circuit block is active. FIGS. 1 and 2 illustrate typically configurations for a power switch cell featuring a header switch and footer switch, respectively.

As shown in FIG. 1, an exemplary power switch cell 100 includes gating header switch (GHS) 102 that may be implemented using a PMOS. When a control signal is applied to the gate 104 of switch 102 to turn it ON, external voltage supply vdd_ext 106 is coupled to virtual voltage rail vddfx 108. As a result, cell 110 is energized and current flows to internal or external ground rail vssfx 112. Similarly, FIG. 2 shows another exemplary power switch cell 200 that includes gating footer switch (GFS) 202 that may be implemented using an NMOS. When a control signal is applied to the gate 204 of switch 202 to turn it ON, external ground vss_ext 206 is coupled to virtual ground rail vssx 208. This activates cell 210 by allowing current to flow from external voltage supply rail vdd_ext 212 to vssx 208.

Preferably, voltage drop from source to drain is small when the MOSFET switch cell is active, such as on the order of 10 mV. The ON resistance Rₒₙ in the linear region may be expressed by equation (1) as follows:

Rₒₙ=1/[Cₒₓ*μ*(W/L)*(V_{gs}−Vₜₕ)] (1)

where Cₒₓ is the oxide capacitance; μ is the electron mobility; W is the width of the gate; L is the length of the gate; V_{gs} is the voltage differential between the gate and the source; and Vₜₕ is the threshold voltage of the gate. In particular, equation (1) indicates that Rₒₙ is proportional to the length of the gate divided by its width (L/W.) Conventional architectures take advantage of this relationship by employing long channel, large width devices to reduce current leakage and provide low ON resistance.

However, another important criterion to consider in the design of the power gating strategy featuring header or footer switches is the area efficiency of the switch. For example, the area penalty of a switch may be expressed as the percentage of area consumed by a switch such that the area penalty equals the area of the switch divided by the area supported by the switch. FIG. 3 illustrates a grid-type power gating technique implemented in a 45 nm CMOS process having a first metal layer, such as layer 3, formed by alternating supply and ground rails vddx 300 and vssfx 302. A second metal layer, such as layer 6, includes perpendicular oriented alternating supply and ground rails vddx 304 and vssx 306. As shown, the ground rails are connected to an external ground (not shown) by switches 308, such that each switch controls a specific region of the grid. For example, switch 308a operates area 310. At this scale, the rails in the first layer may be 0.32 μm wide and the spacing of the supply and ground pair may be 8.4 μm while the rails in the second layer may be 4.2 μm wide and the supply and ground pairs may be spaced at 30.24 μm.

For comparison, FIG. 4 illustrates an equivalent design implemented in a 28 nm CMOS process. As shown, a first metal layer is formed by alternating supply and ground rails vddx 400 and vssfx 402 and a second metal layer includes perpendicular alternating supply and ground rails vddx 404 and vssx 406. The ground rails are connected to an external ground (not shown) by switches 408 controlling the corresponding regions of the grid, such as switch 408a which operates area 410. At this scale, the rails in the first layer may be 0.21μm wide and the spacing the supply and ground pair may be 5.8 μm while the rails in the second layer may be 2.9 μm wide and the supply and ground pairs may be spaced at 21.2 μm. By moving to the smaller process, the area penalty increases.

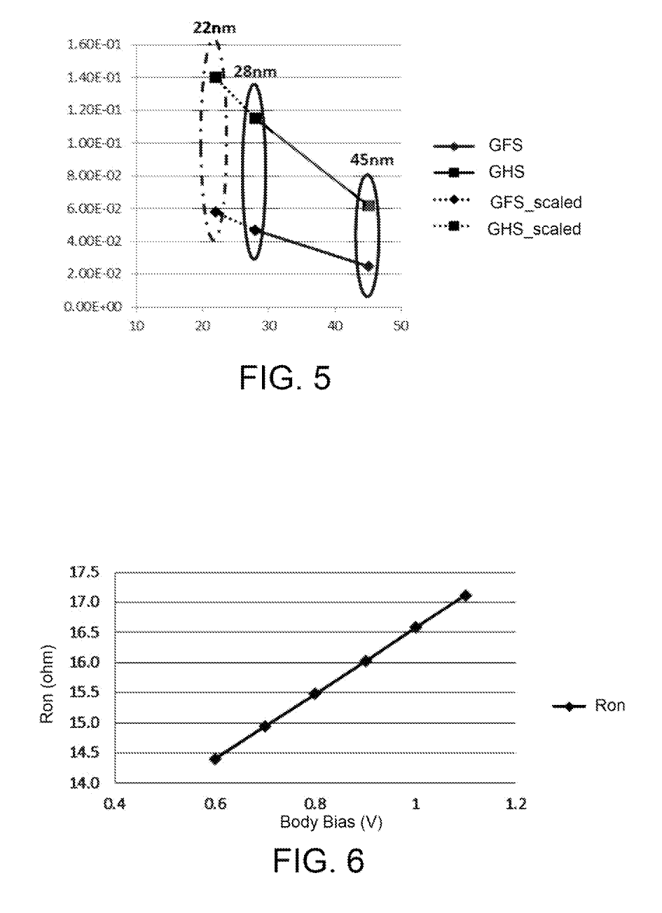

FIG. 5 graphs the area penalty associated with the process scale used. As shown, moving from a 45 nm process to a 28 nm process represents a nearly 100% increase in the area penalty. Furthermore, it is anticipated that further reductions in scale will result in similar increases in area penalty. The dashed lines indicate that moving to a 22 nm process may result in an estimated 20% increase in area penalty. In general, the area penalty of switch cell may increase by the reciprocal ratio of the square of the scaling factor. FIG. 5 also illustrates that the area penalty is relatively greater for a GHS compared to a GFS. However, the use of GHS-based power gating may be desired to decrease the large bulk leakage in OFF mode as a GHS may use a local bulk connection while a GFS may not connect locally using conventional bulk processes. As a result, the techniques of this disclosure may be especially desirable to counteract the increased area penalty associated with designs that employ header switches.

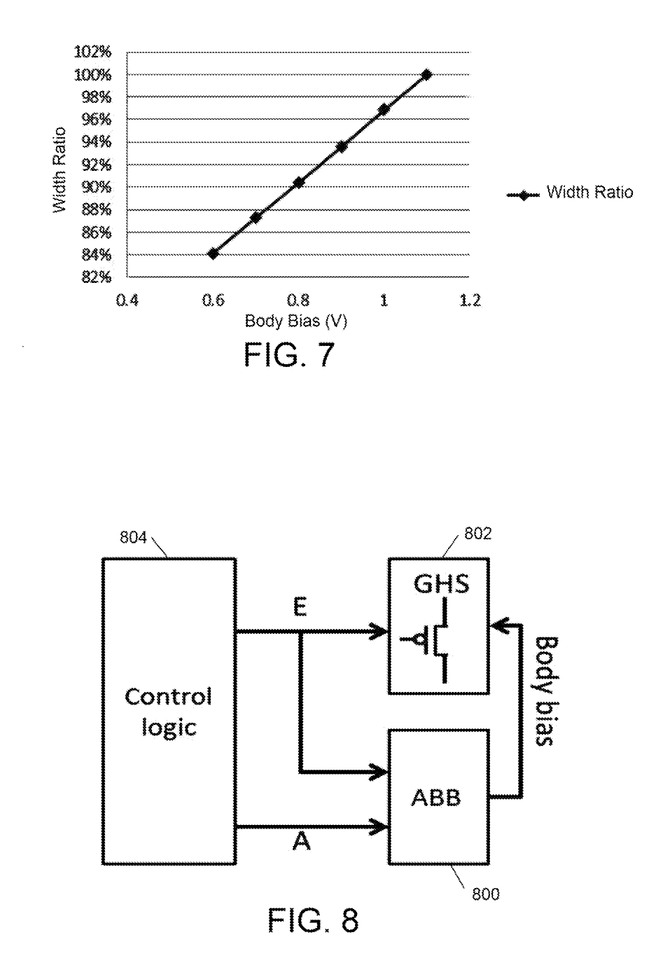

As an alternative to increasing the area of a switch to obtain a suitably low Rₒₙ, a forward body bias voltage may be applied to a MOSFET. FIG. 6 graphs the relationship of body bias voltage to Rₒₙ for a standard voltage threshold (SVT) PMOS having a width of 100 μm suitable for use in a 40 nm CMOS process. Similar characteristics exist for switches of different dimensions that may be used in different scale processes. As can be seen, reduction of body bias from a nominal 1.1 V may result in a significant reduction of Rₒₙ. Further, FIG. 7 graphs the relationship of body bias voltage to the width ratio required to maintain an equivalent Rₒₙ. For example, by using a forward body bias voltage of 0.7 V as compared to 1.1 V, the width, and correspondingly the area, of a switch may be reduced by over 10%.

Accordingly, the techniques of this disclosure involve the use of the ABB module to control the body bias applied to the switching transistor of power switch cell. As depicted schematically in FIG. 8, ABB module 800 is configured to supply a first body bias voltage to PMOS GHS 802 when in an OFF mode and a second body bias voltage when in an ON mode. Control logic 804 generates signals E and A to coordinate operation of GHS 802 and ABB module 800. The first body bias voltage may be greater than the second body bias voltage to increase the threshold voltage so that GHS 802 exhibits high impedance and low current leakage when OFF. Correspondingly, as the second body bias voltage may be less than the first body bias voltage, a forward bias is applied to reduce the threshold voltage so that GHS 802 exhibits decreased Rₒₙ when in the ON mode. Although depicted with regard to a header switch, one of skill in the art will recognize that ABB module 800 may also be used to adapt the body bias applied to an NMOS footer switch in a similar manner.

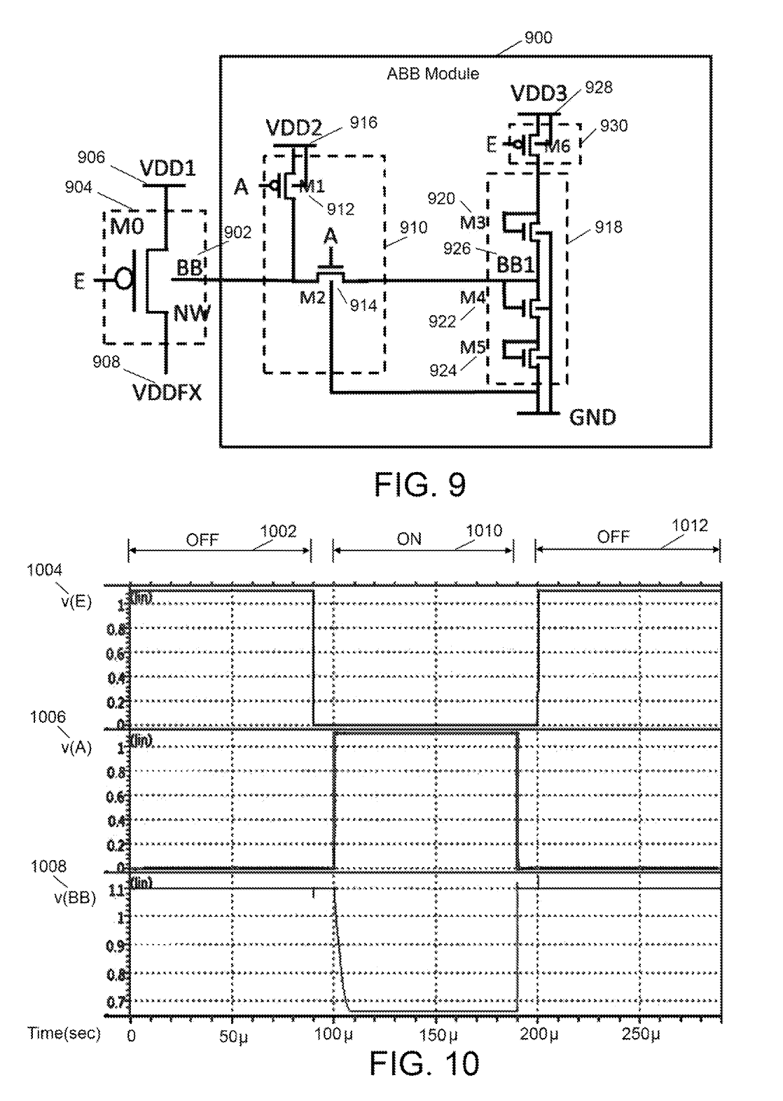

A circuit schematic for one embodiment of a power switch cell having an ABB module is depicted in FIG. 9. As shown, ABB module 900 is connected to body node BB 902 of GHS 904. GHS 904 may be a PMOS MO having a source connected to external voltage supply VDD1 906 and a drain that supplies virtual supply voltage VDDFX 908 to the circuit block controlled by the power switch cell when in an ON mode. GHS 904 has a gate that receives control signal E from the control logic (not shown in this view.) In particular, signal E from the control logic may be set to logical ‘1’ when the cell is to be OFF and logical ‘0’ when the cell is to be ON. ABB module 900 outputs a body bias voltage to node BB 902 that depends upon adaptive switch 910 formed by PMOS M1 912 and NMOS M2 914 that receive control signal A at their respective gates. In this embodiment, control signal A may be the inverse of control signal E. Therefore, when signal E is set to logical ‘0’ to turn the power switch cell ON, signal A is set to logical ‘1,’ placing M1 912 in cutoff mode to disconnect external voltage supply VDD2 916, while M2 914 is in saturated active mode to conduct current between its source and drain and thus supplies a voltage produced by body bias generator 918 to node BB 902. Correspondingly, when signal E is set to logical ‘1,’ signal A is set to logical ‘0,’ so that M1 912 may be placed in active mode and couple VDD2 916 to node BB 902, while M2 914 is in cutoff mode to disconnect body bias generator 918. According to the techniques of this disclosure, the voltage produced by body bias generator 918 may be less than VDD2 916 so that a forward bias is applied to GHS 904 when the power switch cell is active in ON mode, reducing the threshold voltage Vₜₕ of GHS 904.

In the embodiment shown, body bias generator 918 may be formed from three NMOS connected in series, M3 920, M4 922 and M5 924. The series connected NMOS have their drains connected to their gates to form diode-connected transistors that may operate in moderate inversion mode. This configuration may be used to generate the voltage output of body bias generator 918 at node BB1 926, which is formed by the junction of the drain of M4 922 and the source of M3 920. As described above, the voltage output of body bias generator 918 is fed to node BB 902 when M2 914 is activated by control signal A being set to logical ‘1.’

Voltage may be supplied to body bias generator 918 from external voltage supply VDD3 928. To reduce current leakage through body bias generator 918 when disconnected from node BB by M2 914, a body bias switch such as PMOS M6 930 may be configured to pinch off VDD3 926 in response to control signal E. Specifically, M6 930 may be in cutoff mode when signal E is set to logical ‘1’ and the voltage output from body bias generator 918 is not needed. As will be appreciated, similar functionality may be achieved using an NMOS responsive to control signal A or through other suitable switching techniques.

In the configuration shown, the voltage output by body bias generator 918 may be approximately ⅔ of the voltage at VDD3 928. It may be desirable to use MOSFETs of the same size and specification for M3 920, M4 922 and M5 924 to minimize variation and mismatch. Although the embodiment shown employs three NMOS to form body bias generator 918, other embodiments may generally use a plurality of MOSFETs connected in series, such as two, three or four PMOS or two or four NMOS. Further, as indicated by FIG. 6, relatively small changes in the body bias voltage correspond to a relatively small change in Rₒₙ. For example, in the exemplary 100 μm GHS PMOS depicted, the ON resistance may change approximately 3.5% when the body bias voltage changes 0.1V. From this it will be appreciated that body bias generator 918 need not provide a highly accurate voltage.

In one aspect, VDD1 906, VDD2 916 and VDD3 928 may be supplied by the same external voltage supply, VDD, so that the first body bias voltage applied to GHS 904 when in OFF mode is VDD and the second body bias voltage applied to GHS 904 when ON is ⅔ VDD. As will be appreciated, using the same external voltage supply represents an efficient design with respect to the area consumed by ABB module 900. However, in other embodiments it may be desirable to employ different relative values of the supply voltages. For example, the use of a relatively larger VDD2 may be employed to provide a higher threshold voltage for GHS 904 when the power switch cell is OFF to reduce leakage. In addition, the use of a relatively smaller VDD3 may be employed to provide a reduced threshold voltage for GHS 904 and minimize resistance when the cell is ON.

An example of the operation of ABB module 900 is represented by FIG. 10 which depicts the voltage output to node BB 902 in relation to the voltages of control signals A and E in the ON and OFF modes of GHS 904. In this example, VDD1 906, VDD2 916 and VDD3 928 share a common supply voltage of 1.1 V. Specifically, in an initial OFF mode designated by the period 1002, the voltage of control signal E, v(E) 1004, may be 1.1 V representing a logical ‘1,’ the voltage of control signal A, v(A) 1006, may be 0 V representing a logical ‘0,’ and the voltage output by ABB module 900 to node BB 902, v(BB) 1008, may be 1.1 V as VDD2 916 is coupled to node BB 902 by M1 912 and body bias generator 918 is disconnected by M2 914. When the power switch cell is activated as indicated by period 1010, the control logic outputs a signal E set to a logical value of ‘0’ so that v(E) 1004 may be 0 V and outputs a signal A set to a logical value of ‘1’ so that v(A) 1006 may be 1.1 V. Accordingly, the output of body bias generator 918 at node BB1 926 is coupled by M2 914 to node BB 902 and VDD2 916 is disconnected by M1 912. As discussed above, the configuration of body bias generator 918 results in an output voltage of approximately ⅔ VDD3 928 at node BB1 926 so that v(BB) 1008 may be approximately 0.7 V. The reduction of voltage output to node BB 902 represents a forward body bias that decreases the Vₜₕ to lower the Rₒₙ as described above. v(E) 1004 may return to 1.1 V representing a logical ‘1’ v(A) 1006 may return to 0 V representing a logical ‘0’ when the control logic deactivates the power switch cell, the OFF mode designated by the period 1012. Correspondingly, activation of M1 916 and deactivation of M2 914 returns v(BB) 1008 to 1.1 V, removing the forward bias. The increased body bias voltage applied to node BB 902 correspondingly represents a higher operating Vₜₕ for GHS 904 to reduce current leakage as compared to the ON mode.

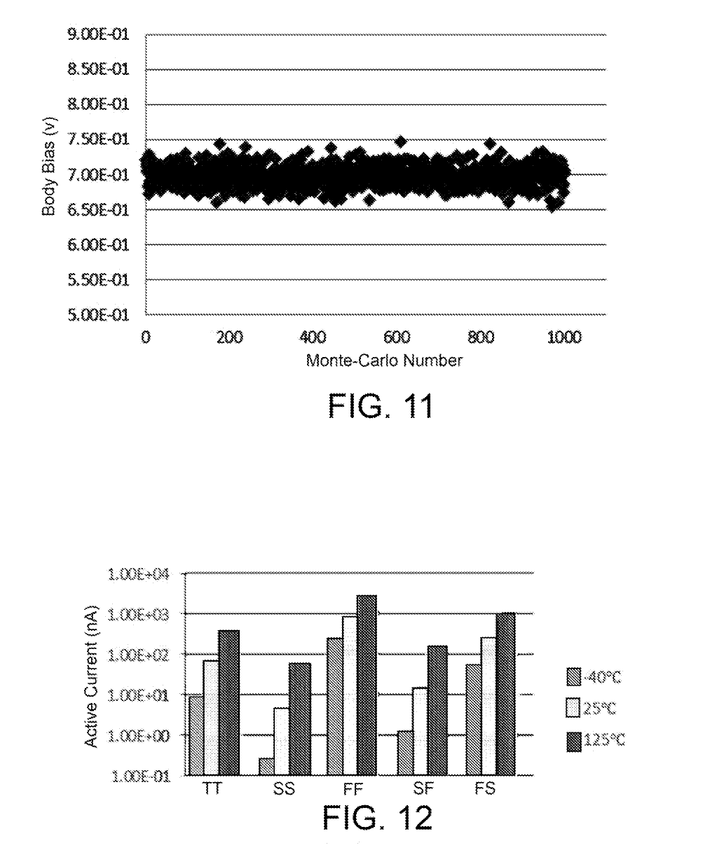

Further simulations of the operation of ABB module 900 are depicted in FIGS. 11-13 with regard to the voltage generated by body bias generator 918 and the active and standby current consumption at signoff corners including typical typical (TT), slow slow (SS), fast fast (FF), slow fast (SF) and fast slow (FS.) These simulations represent the function of ABB module 900 as shown in FIG. 9 employing MOSFETs having the characteristics given in Table 1.

TABLE 1

| MOSFET | Type | W/L |
|---|---|---|
| M1 | SVT PMOS | 0.2 μm/60 nm |
| M6 | SVT PMOS | 0.5 μm/60 nm |
| M2 | SVT NMOS | 0.5 μm/60 nm |
| M3-M5 | SVT NMOS | 0.5 μm/40 nm |

FIG. 11 depicts the body bias voltage output by node BB1 926 by body bias generator 918 resulting from a Monte-Carlo method that simulates multiple, random samples of the output voltage at the TT corner and 25° C. As shown, the body bias generated occurs in a relatively tight range around 0.65-0.75 V. The use of a body bias in this range preferably does not cause GHS 904 to exhibit a parasitic diode effect.

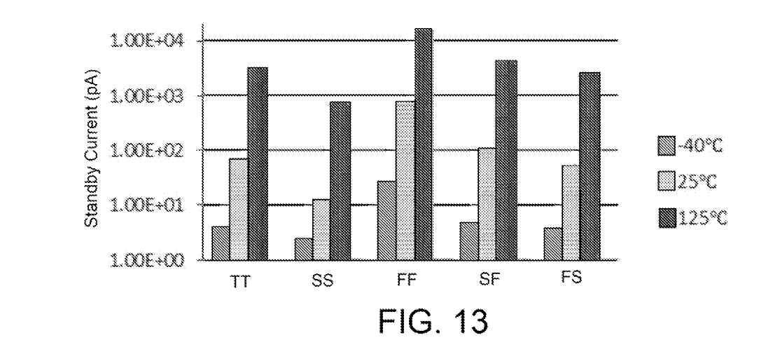

Next, FIG. 12 depicts the active current consumed by ABB module 900. As can be seen, the active current consumed in nominal operation at a TT corner at 1.1 V and 25° C. may be approximately 76 nA. Under more extreme conditions, the largest current consumed may be seen to occur at an FF corner at 1.21 V and 125° C. and may be approximately 3.2 μA. One of skill in the art will appreciate this represents less than 0.5% of the general current output of a 100 μm PMOS in this corner. Similarly, FIG. 13 depicts the standby current consumed by ABB module 900. Typical operation is represented by TT corner at 25° C. and may result in current consumption of less than approximately 100 pA. The worst case may be seen in relation to the FF corner at 1.21 V and 125° C. and represents a current consumption of approximately 3.7 nA.

The above simulations indicate that the implementations of ABB module 900 of this disclosure represent a robust and power efficient technique of controlling the body bias applied to a power gating switch.

Described herein are presently preferred embodiments. However, one skilled in the art that pertains to the present invention will understand that the principles of this disclosure can be extended easily with appropriate modification.

What is claimed is:

1. A circuit for adjusting a body bias voltage applied to a power gating switch, comprising:
a first supply voltage;
a body bias generator formed from a plurality of series connected MOSFETs coupled to a second supply voltage, wherein a body bias generator output is taken from a node between a source of a first MOSFET of the plurality of series connected MOSFETs and a drain of a second MOSFET of the plurality of series connected MOSFETs; and
an adaptive switch providing an output coupled to either the first supply voltage or the node of the body bias generator;
wherein the output of the adaptive switch is a first body bias voltage when coupled to the first supply voltage and is a second body bias voltage when coupled to the node of the body bias generator such that the first body bias voltage is greater than the second body bias voltage when configured as a gating header switch and the first body bias voltage is less than the second body bias voltage when configured as a gating footer switch.

2. The circuit of claim 1, further comprising a power gating switch having a body node operatively coupled to the output of the adaptive switch.

3. The circuit of claim 2, wherein the power gating switch is a PMOS gating header switch.

4. The circuit of claim 2, wherein the power gating switch is an NMOS gating footer switch.

5. The circuit of claim 2, further comprising control logic configured to generate control signals to operate the power gating switch and the adaptive switch.

6. The circuit of claim 5, wherein the power gating switch comprises a PMOS gating header switch and wherein the control logic is configured to generate a first control signal and a second control signal that is the inverse of the first control signal such that the first control signal is applied to a gate of the gating header switch to activate the gating header switch when the first control signal is set to a logical ‘0’ and the second control signal causes the adaptive switch to output the second body bias voltage and such that the first control signal is applied to the gate of the gating header switch to deactivate the gating header switch when the first control signal is set to a logical ‘1’ and the second control signal causes the adaptive switch to output the first body bias voltage.

7. The circuit of claim 6, wherein the adaptive switch comprises a PMOS having a source connected to the first supply voltage, a drain connected to the output of the adaptive switch and a gate receiving the second control signal and an NMOS having a drain connected to the node of the body bias generator, a source connected to the output of the adaptive switch and a gate receiving the second control signal.

8. The circuit of claim 1, further comprising a body bias switch configured to selectively couple the second supply voltage to the plurality of series connected MOSFETs when the output of the adaptive switch is coupled to the node of the body bias generator.

9. The circuit of claim 1, wherein the plurality of series connected MOSFETs operate in a moderate inversion mode when the output of the adaptive switch is coupled to the node of the body bias generator.

10. The circuit of claim 1, wherein the first supply voltage is the same as the second supply voltage.

11. A method for adjusting a body bias voltage applied to a power gating switch, comprising:
providing an adaptive body bias module having a first supply voltage, a body bias generator formed from a plurality of series connected MOSFETs coupled to a second supply voltage, wherein a body bias generator output is taken from a node between a source of a first MOSFET of the plurality of series connected MOSFETs and a drain of a second MOSFET of the plurality of series connected MOSFETs, and an adaptive switch having an output;
generating a first body bias voltage by coupling the output of the adaptive switch to the first supply voltage; and
generating a second body bias voltage by coupling the output of the adaptive switch to the node of the body bias generator,
wherein the first body bias voltage is greater than the second body bias voltage when the adaptive body bias module is configured as a gating header switch and the first body bias voltage is less than the second body bias voltage when configured as a gating footer switch.

12. The method of claim 11, further comprising providing a power gating switch having a body node operatively coupled to the output of the adaptive switch.

13. The method of claim 12, wherein the power gating switch is a PMOS gating header switch, further comprising operating the gating header switch in an OFF mode when generating the first body bias voltage and operating the gating header switch in an ON mode when generating the second body bias voltage.

14. The method of claim 12, wherein the power gating switch is an NMOS gating footer switch, further comprising operating the gating footer switch in an OFF mode when generating the first body bias voltage and operating the gating footer switch in an ON mode when generating the second body bias voltage.

15. The method of claim 12, further comprising generating control signals configured to operate the power gating switch and the adaptive switch.

16. The method of claim 15, wherein the power gating switch comprises a PMOS gating header switch further comprising:
applying a first control signal set to logical ‘0’ to a gate of the gating header switch to activate the gating header switch and a second control signal set to logical ‘1’ to the adaptive switch to cause the adaptive switch to output the second body bias voltage; and
applying the first control signal set to logical ‘1’ to the gate of the gating header switch to deactivate the gating header switch and the second control signal set to logical ‘0’ to the adaptive switch to cause the adaptive switch to output the first body bias voltage.

17. The method of claim 16, wherein the adaptive switch comprises a PMOS having a source connected to the first supply voltage, a drain connected to the output of the adaptive switch and a gate receiving the second control signal and an NMOS having a drain connected to the node of the body bias generator, a source connected to the output of the adaptive switch and a gate receiving the second control signal.

18. The method of claim 11, further comprising selectively coupling the second supply voltage to the plurality of series connected MOSFETs when the output of the adaptive switch is coupled to the node of the body bias generator.

19. The method of claim 11, further comprising operating the plurality of series connected MOSFETs in a moderate inversion mode when the output of the adaptive switch is coupled to the node of the body bias generator.

20. The method of claim 11, wherein the first supply voltage is the same as the second supply voltage.
